(19) United States
(12) Patent Application Publication
(10) Pub. No.: US 2010/0034072 A1
(43) Pub. Date: Feb. 11, 2010

(54) FRESNEL MEMBER HAVING VARIABLE SAG FOR MULTIPLE WAVELENGTH OPTICAL SYSTEM

(75) Inventor: Yosuke MIZUYAMA, Boston, MA (US)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/333,895

(22) Filed: Dec. 12, 2008

Related U.S. Application Data
(60) Provisional application No. 61/086,895, filed on Aug. 7, 2008.

(51) Int. Cl. G11B 7/00; G02B 3/08; G03F 7/20

(52) U.S. Cl. 369/112.23; 359/742; 430/321; G9B/7

(57) ABSTRACT

A Fresnel member for an optical system is configured to receive at least reflected light having a first wavelength at a first envelope and reflected light having a second wavelength different from the first wavelength at a second envelope. The Fresnel member includes a plurality of ring zone portions having predetermined surface heights for achieving a maximum diffraction efficiency.

### CROSS-REFERENCE TO RELATED APPLICATION

The present application claims the benefit of priority of U.S. Provisional Application No. 61/086,895 filed on 7 Aug. 2008.

### TECHNICAL FIELD

The technical field relates generally to optical systems and, more particularly, to a Fresnel member used in such optical systems.

### BACKGROUND

An optical system can include a light source for emitting a laser beam having multiple wavelengths toward an optical disk. The wavelengths can be, for example, 665 nm for a Digital Versatile Disk or Digital Video Disk (hereafter: “DVD”) and 790 nm for a compact disk (hereafter: “CD”).

The emitted laser beam can travel through gratings, an integrated prism, a phase plate, a collimator, and an objective lens until it reaches a surface of the optical disk. At least a portion of the optical beam can be reflected by the optical disk, and returned through the same path up to a slope of the integrated prism. The returned beam can be reflected by the slope rather than being transmitted and redirected to a detection lens and an optical receiver.

### SUMMARY

An optical pickup device or system (hereafter: “optical device”) according to novel embodiments may include a Fresnel mirror or lens (hereafter: “Fresnel member”) as the detection lens and a photo-detector as the optical receiver.

In the optical device, light associated with the laser beam can be reflected by or transmitted through the Fresnel member to form a substantially circular image on the photo-detector having two focal points in the vicinity of the photo-detector. A focal point of the light on a cross section in the vertical direction is positioned ahead of the photo-detector, and a focal point of the light on a cross section in the horizontal direction is positioned behind the photo-detector. That is, the photo-detector is disposed between the two focal points.

While the objective lens in the optical device scans the optical disk horizontally and vertically to obtain the focus and the track for writing/reading pits on which information is represented, the laser beam image at the photo-detector can be used by electronics to find the focus position and correct track position for the optical disk.

Particularly, when the optical disk is close to the objective lens, the image of a laser beam in the photo-detector becomes elongated in the diagonal direction. On the other hand, when the optical disk is far from the objective lens, the image becomes elongated in the other diagonal direction. (The Fresnel member is placed so that the elongated image extends in a diagonal direction on the photo-detector.)

FIG. 1 shows ideal images at the photo-detector when the optical disk moves through focus. However, in practice, the actual detector images may be distorted and scattered, particularly for one of two wavelengths due to optical aberration caused by wavelength dispersion.

The photo-detector converts the laser beam intensity to an electric signal. However, if the Fresnel member for the optical device is designed based solely on a laser beam associated with a DVD, a laser beam associated with a CD will become degraded and give scattered and stray light, thereby adding noise to the electric signal.

Moreover, movement of the laser beam around on the Fresnel member while the objective lens scans the optical disk to read different tracks can cause temporal irregular illumination on the photo-detector. Further temporal irregularity in the electric signal can occur for a double layer DVD disk of approximately 9.4 GB if the disk is a low grade which does not have constant layer separation due to background stray light from one of the two layers moving around on the Fresnel member when the disk is spinning.

That is, the electric signal behaves differently for laser beams associated with DVD and CD, one of which is degraded and unstable in signal quality.

A conventional Fresnel member can include a plurality of ring zones having uniform surface height or so-called sag over the lens size. However, the design of the Fresnel member is based upon the faulty assumption that there is no fabrication error. That is, as shown in FIG. 5C, it is difficult to achieve a ring zone in which the wall portions or so-called facets are uniformly vertical. The actual Fresnel member often has zones with non-perpendicular facets which introduce a certain error from design thereby giving degradation of optical performance.

Accordingly, in view of the above problems, as well as other objectives, the optical device according to various embodiments includes a novel Fresnel member that can improve the quality of focusing and tracking error signals. The Fresnel member is optimized for a practical shape having fabrication error at the facets and for multiple wavelengths. The sag is varied across the lens in a radial direction so that each non-right angle zone has optimal sag for multiple wavelengths. The optimal sag at each zone for each wavelength can be calculated by a rigorous Maxwell equation solver such as GSOLVER. Further, the optimal sag can be determined by the intermediate sag of two optimal sags for each wavelength so that the lens generally has decreasing sag.

The Fresnel member will have improved diffraction efficiency so that multiple wavelengths such as CD/DVD and Blu-ray can be accommodated by the optical disk drive.

### BRIEF DESCRIPTION OF THE DRAWINGS

The accompanying drawings, which are incorporated in and constitute a part of this specification, illustrate various exemplary embodiments and together with the description, serve to explain the principles of the invention.

FIG. 1 is an illustration of ideal laser beam images at a photo-detector of an optical device.

FIG. 2 is an illustration of a layout of an optical device according to an exemplary embodiment.

FIG. 3A is an illustration of an exemplary optical pickup device configuration.

FIGS. 3B-3C are illustrations of exemplary portions of the optical pickup device.

FIG. 4 is an illustration of an exemplary segmented image at the photo-detector.

FIG. 5A is a diagram showing a contour of Fresnel member sag.

FIG. 5B is a graph showing the Fresnel member profile.

FIG. 5C is a diagram illustrating a fabrication error.

FIGS. 6A-6B are diagrams showing methods for designing a Fresnel member according to exemplary embodiments.

FIG. 6C is a diagram illustrating the relationship between incident beam angle and cut depth.

FIG. 7A is a graph showing a relationship between cut depth and diffraction efficiency.

FIGS. 7B-7D are graphs showing a relationship between cut depth and diffraction efficiency for various incident angles.

FIGS. 8A-8H are diagrams illustrating methods for forming a Fresnel member according to exemplary embodiments.

FIGS. 9A-9B are diagrams illustrating arrival positions of the laser beams on the Fresnel member.

FIG. 10A is a graph showing a relationship between incident angle and optimal cut depth.

FIG. 10B is a graph showing a relationship between optimal surface height and position.

FIG. 11 is a diagram showing a distribution of the optimal surface height versus position according to an exemplary embodiment.

FIG. 12 is a diagram showing a distribution of the optimal surface height versus position according to an exemplary embodiment.

FIG. 13 is a diagram showing a distribution of the optimal surface height versus position according to an exemplary embodiment.

FIG. 14 is a diagram showing a distribution of the optimal surface height versus position according to an exemplary embodiment.

FIGS. 15A-15B are diagrams illustrating exemplary Fresnel members formed according to the design methods shown in FIGS. 6A-6B.

FIG. 16 is an illustration of an exemplary segmented image at the photo-detector.

FIGS. 17A-17C are graphs showing a relationship between lens shift and electrical signals.

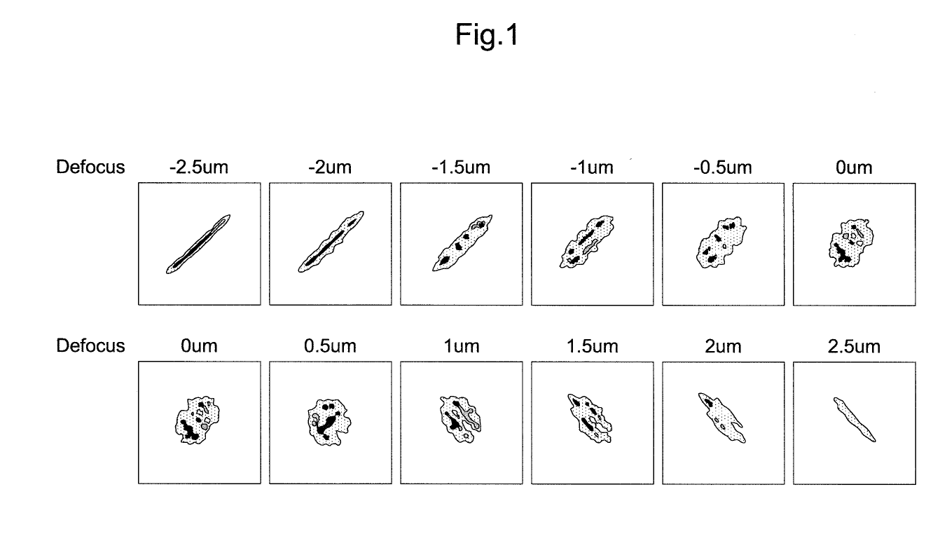

### DETAILED DESCRIPTION

In overview, the present disclosure concerns an apparatus such as an optical system or device in which laser beams of certain wavelengths are transmitted for reading and/or writing data to/from a media such as an optical disk. Such an apparatus can be implemented in, for example, a consumer appliance such as a CD, DVD or Blu-ray player. More particularly, various inventive concepts and principles are embodied in apparatus and methods therein for providing an improved Fresnel member for the apparatus.

The instant disclosure is provided to further explain in an enabling fashion the best modes of performing one or more embodiments of the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

It is further understood that the use of relational terms such as first and second, and the like, if any, are used solely to distinguish one from another entity, item, or action without necessarily requiring or implying any actual such relationship or order between such entities, items or actions. It is noted that some embodiments may include a plurality of processes or steps, which can be performed in any order, unless expressly and necessarily limited to a particular order; i.e., processes or steps that are not so limited may be performed in any order. Embodiments will be described with reference to the accompanying drawings.

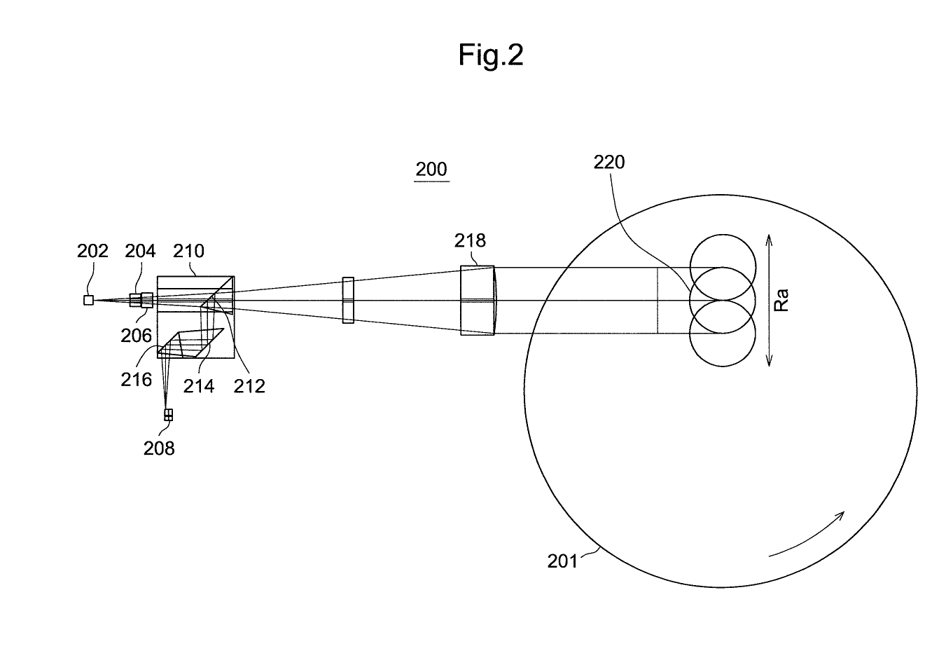

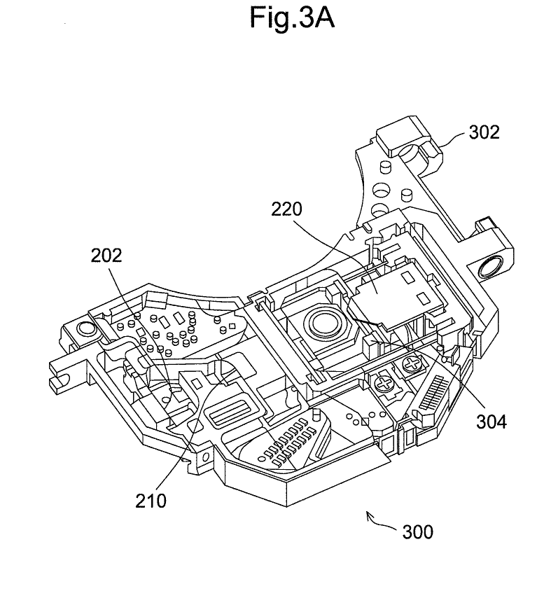

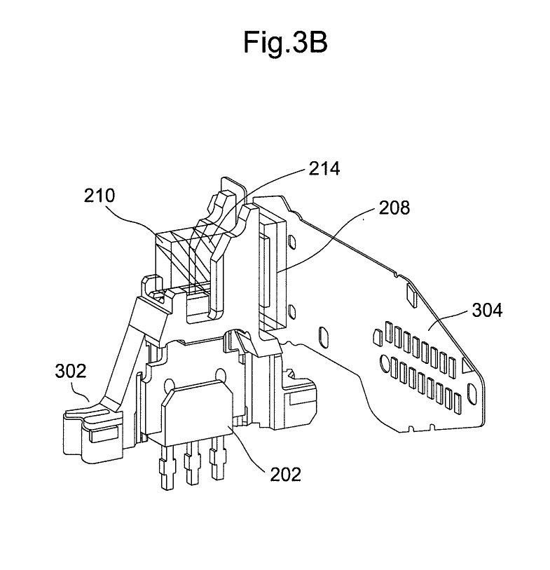

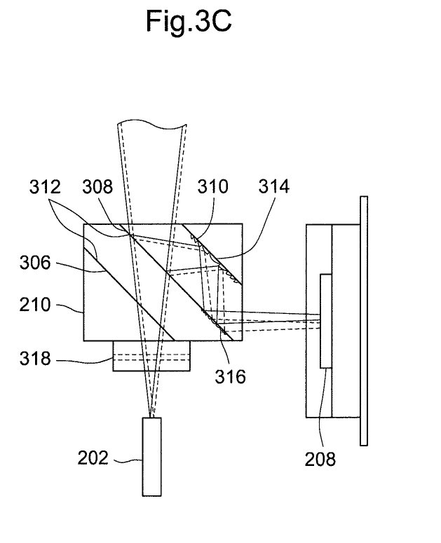

Referring to FIG. 2, an exemplary layout of an optical device 200 according to an embodiment will be discussed. The optical device 200 can include a laser diode 202 for emitting a first laser beam having a first wavelength λ1 such as, for example, 665 nm and a second laser beam having a second wavelength λ2 such as, for example, 790 nm. The device 200 can include first and second diffraction gratings 204, 206 disposed in series. The first diffraction grating 204 diffracts the first laser beam of the first wavelength λ1 into zero-order light or ±1-order light while transmitting the laser beam with the second wavelength λ2 therethrough. The second diffraction grating 206 diffracts the laser having the second wavelength λ2 into zero-order light or ±1-order light while transmitting the first laser beam with the first wavelength λ1 therethrough. Alternatively, the optical device 200 can include a wavelength selective grating (shown in FIG. 3C) rather than the first and second diffraction gratings 204, 206.

The optical device 200 includes an integrated prism 210 having a plurality of parallel slopes (shown in FIG. 3C) therein. A beam splitter 212 formed on one of the slopes transmits the forward laser beams from the laser diode 202 toward an optical disk 201 and reflects laser beams reflected from the optical disk 201, which are return laser beams, toward a Fresnel member 214. The beam splitter 212 can be formed from a polarization separating film of a dielectric multilayer.

The Fresnel member 214 is formed on another one of the slopes. Generally, the Fresnel member 214 can be an astigmatic mirror or lens in which focusing positions on two perpendicular cross sections including an optical axis of light passing therethrough are different from each other. A reflective coating 216 formed on one of the slopes reflects the light from the Fresnel member 214 onto a photo-detector 208.

The photo-detector 208 is disposed such that the focusing position of emitted light on one cross section is located ahead of the photo-detector 208 and the focusing position of reflected light on the other cross-section is located behind. The light transmitted through or reflected by the Fresnel member 214 and incident on the photo-detector 208 has been diffracted into zero-order light or ±1-order light and can be used for focus and tracking control.

The optical device 200 can include a collimator 218 for converting the divergent forward light received from the integrated prism 210 into parallel forward light to be transmitted to an objective lens 220 and converting parallel return light reflected by the optical disk 201 and received via the objective lens 220 into divergent return light. The objective lens 220 scans the optical disk horizontally and vertically to obtain the focus and the track for writing/reading pits on which information is represented.

Referring to FIG. 3A, the optical device can be implemented within a multi-drive 300 for emitting laser beams associated with, for example, DVD and CD. The laser diode 202 and the integrated prism 210 are fixed to a bonding member (not shown) to thereby form a laser module. The bonding member is fixed to a pedestal 302 which is a skeleton of the optical device. The objective lens 220 is mounted in an actuator 304 that drives the objective lens 220.

Referring to FIG. 3B, the integrated prism 210 can be disposed above the laser diode 202 and the photo-detector 208 within the pedestal 302. Also, a flexible printed circuit 304 is coupled to the photo-detector 208 for providing the electronics for processing images of the laser beams received at the photo-detector 208.

Referring to FIG. 3C, the integrated prism 210 can include first and second slopes 306, 308 having first and second PBS (Polarizing Beam Splitter) coatings 312 and a third slope 310 having a grayscale diffractive astigmatic mirror 314, which constitutes the Fresnel member in this embodiment. A reflective coating 316 is disposed on a portion of the second slope 308. Also, a wavelength selective grating 318 is disposed in front of the prism 210 for diffracting light from the laser diode 202. The PBS coatings 312 on the first and second slopes 306, 308 allow the forward light to pass therethrough while the PBS coating 312 on the second slope 308 reflects the return light to the Fresnel member 314, which directs the return light to the photo-detector 208 via the reflective coating 316 on the second slope 308.

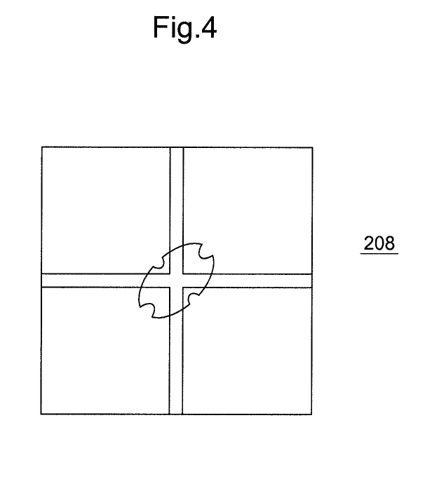

Referring to FIG. 4, the photo-detector 208 can be a quad-detector segmented into 4 sensible parts, each of which converts the laser beam intensity illuminated on the part to an electric signal.

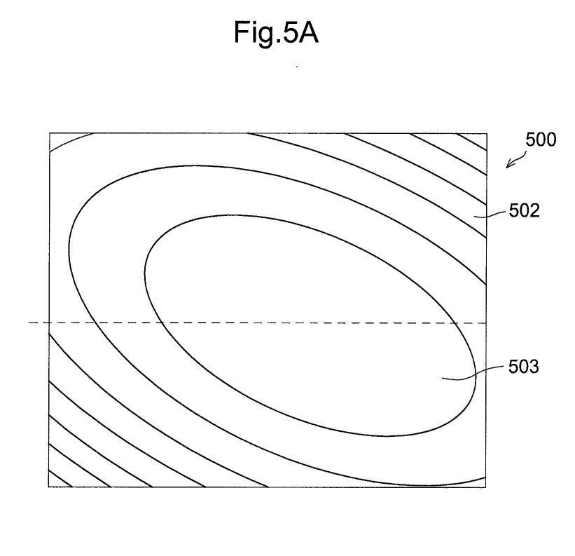

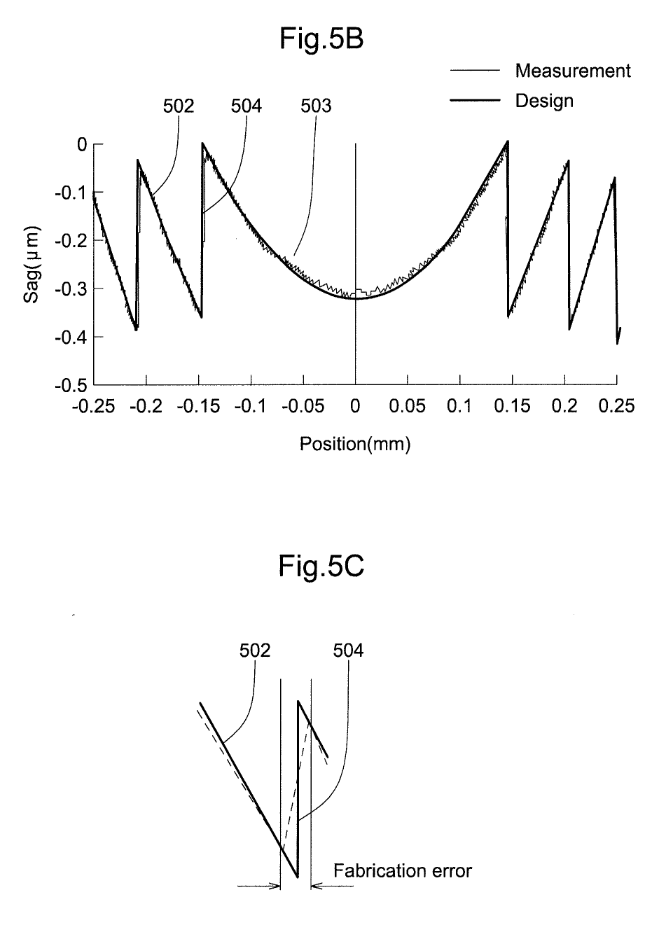

Referring to FIG. 5A, an exemplary Fresnel member 500 for the optical system will be discussed. The Fresnel member 500 design is based from a thin version of a regular curved surface mirror or lens which is configured to include a plurality of orbicular band shaped reflecting mirrors or lens 502 surrounding a curve-shaped central portion 503 in order to make a normal three-dimensional curved mirror more compact. The reflecting mirrors or lens 502 can be, for example, orbicular band or curve shaped, and will be referred to here simply as ring zones 502. A surface depth (shown in FIGS. 5B and 5C) of wall portions 504 or facets on the boundary between the ring zones 502 adjacent to each other can be referred to as sagitta or sag. As will be discussed more fully below, the sag can be continuously folded at predetermined depths until the total height becomes a predetermined cut depth to design the Fresnel member 500. Contours of the surface height or “sag” are shown in FIG. 5A. A profile of the sags along the dotted line of FIG. 5A is shown in FIG. 5B.

The Fresnel member 500 has a discontinuity between adjacent ring zones which can cause wavelength dispersion. Ideally, the wall portion 504 at the discontinuity is vertically shaped (perpendicular) as shown in FIG. 5B. However, due to a fabrication error referred to as blurring, the walls 504 may have a slope, which gives rise to degradation of focus/tracking signal. The difference between an ideal vertically shaped wall and slope shaped wall at the discontinuity is shown in FIG. 5C.

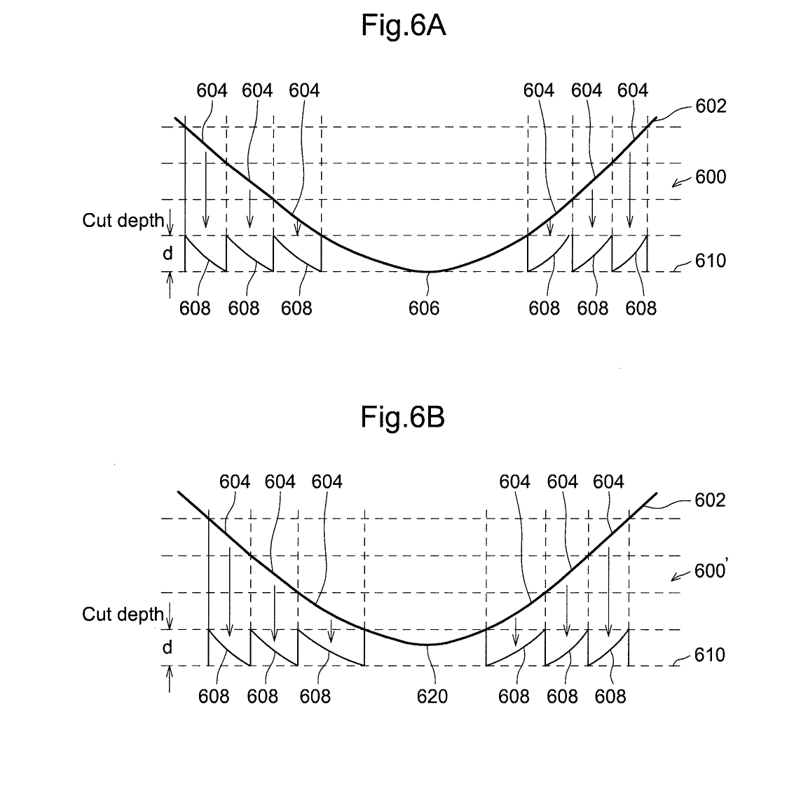

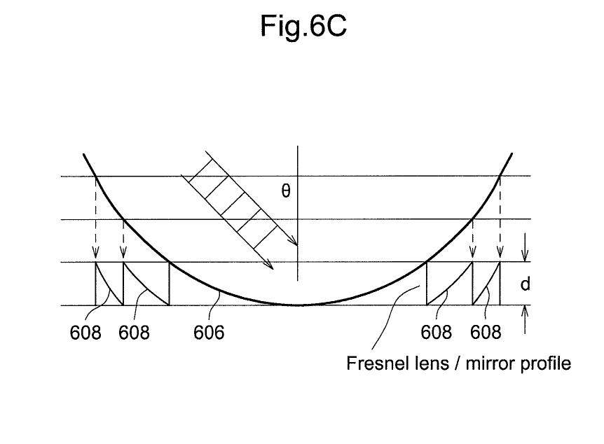

Referring to FIG. 6A, an exemplary method for designing a Fresnel member 600 will be discussed. In this example, the Fresnel member 600 is designed from an original continuous lens/mirror 602. A plurality of predetermined portions 604 surrounding a substantially curve-shaped central portion 606 of the continuous lens/mirror 602 are cut by a predetermined cut depth d and cut width to form a plurality of ring zones 608, which are folded to a base line 610 tangent to the vertex of the original lens/mirror 602.

The manner of folding the lens/mirror 602 depends on the base line position from which the lens/mirror is cut. Different folding makes a different shape of a Fresnel lens/mirror, which makes a slight difference in optical performance.

Referring to FIG. 6B, a Fresnel member 600′ is designed based upon a base line 610 which is offset from a vertex of the central portion 620. Particularly, after cutting the plurality of predetermined portions 604 surrounding the central portion 620 by the predetermined cut depth d and cut width, the ring zones 608 are folded down to the offset base line 610. As a result, the central portion 620 of the Fresnel member 600′ has a peak surface height that is less than the surface heights of each of the plurality of ring zones 608.

Referring to FIG. 6C, the optical cut depth for the ring zones 608 of the Fresnel member may be provided by formula (1):

$$d = \frac{m λ}{2 n cos θ} .$$

In formula 1, d is the depth of a cut for the Fresnel member for an incident beam at angle θ, m is the diffraction order of the transmitted or reflected light, and n is the refractive index of the surrounding material. m will usually be an integer equal to a value such as 1 or 2.

Generally, by determining the cut depth d in accordance with formula (1), the Fresnel member can be designed by cutting the predetermined portions of the continuous mirror so that a predetermined surface height of each of ring zone portions of the ring zones in the first envelope is equal to the value d, at which the reflected light of the first wavelength incident at an incident angle with the each of the ring zone portions has a maximum diffraction efficiency, and so that a predetermined surface height of each of ring zone portions of the ring zones in the second envelope is equal to the value d at which the reflected light of the second wavelength incident at an incident angle with the each of the ring zone portions has a maximum diffraction efficiency.

However, a depth achieved solely by formula 1 is based on a theoretical scalar theory. That is, this approach for achieving the depth does not take into account optical systems in which the laser beams have multiple wavelengths, or when the beam is collimated (parallel). A converging/diverging beam has a different angle of incidence than the center ray.

A more accurate depth can be obtained by a rigorous vector theory. Commercial software such as GSOLVER can be used to simulate the vector theory. In this simulation, the shape distortion effect due to fabrication error and the incident angle effect can be taken into account to determine a more accurate depth. The simulated results can be obtained based upon: (1) the light wavelength; (2) the (Grating) Period; (3) the incident angle; (4) the refractive indices; (5) depth; (6) (Grating) Shape; and (7) Polarization.

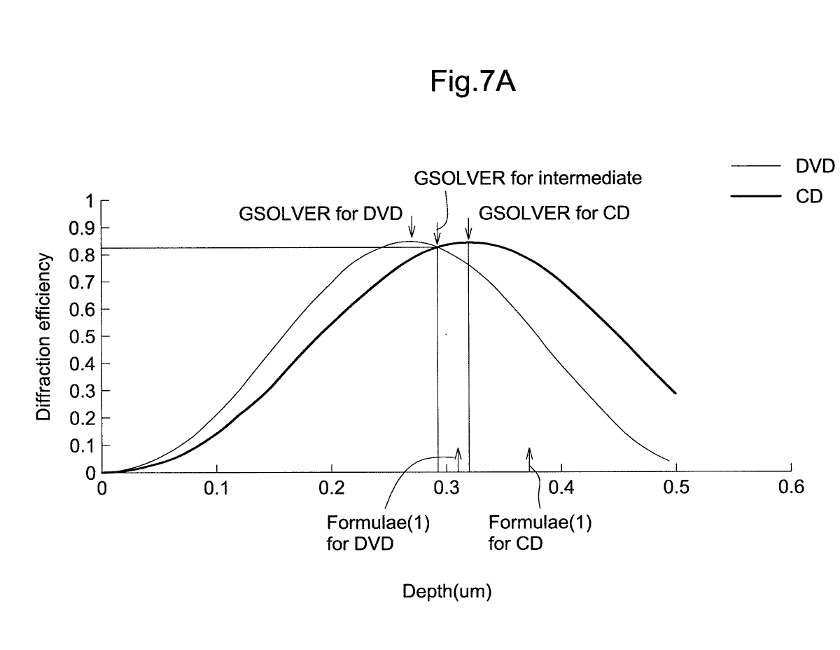

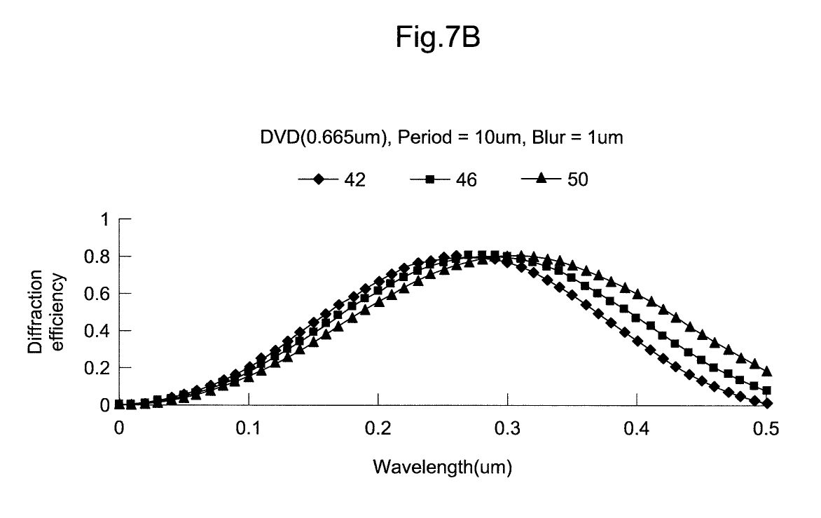

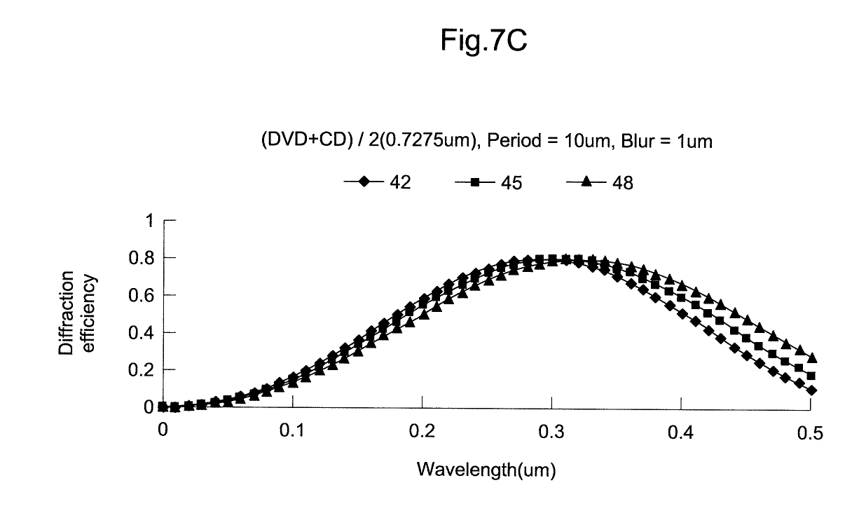

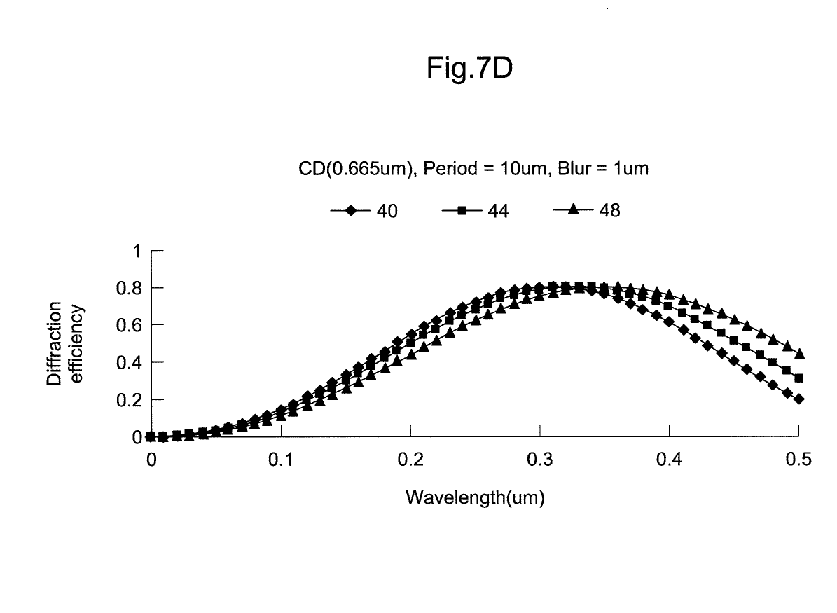

Referring to FIG. 7A, results of a GSOLVER calculation are shown for a diffraction efficiency of the ⁻1st diffraction order for the case of 45 degree incidence for a 10 micrometer period including the effect of 1 micrometer blurring at break. Compared to the optimal cut depth achieved by formula 1, more accurate optimal cut depths for DVD and CD are shown to be 10-15% shallower.

Referring to FIGS. 7B-7D, simulated diffraction efficiencies versus depths were obtained at 42, 46 and 50 degrees for light having a wavelength associated with a DVD (665 nm), light associated with an intermediate wavelength (727.5 nm) and light associated with a CD (790 nm).

The optimal cut depth varies with incident angle. The GSOLVER simulation results illustrated in FIGS. 7B-7D show that the optimal cut depth is shifted to a larger side as the incident angle increases. This is true for all DVD, CD and intermediate wavelengths.

The best cut depth (or surface height) for each local point on the Fresnel member is preferably obtained based upon these calculation results. For a given wavelength and an incident angle, the optimal depth can be determined from the graph. The distribution of the wavelength and incident angle depends on how the DVD and CD beams arrive on to the Fresnel member.

The Fresnel member can be manufactured by using photolithography techniques such as a grayscale mask allowing exposure in a predetermined shape whose transmittance with respect to light having a wavelength used for exposure changes continuously with a location in a portion equivalent to the ring zones. By using the grayscale mask, the depth of the level difference and the curved shape of the continuous shape of the ring zones, which is the original shape of the mirror, can be realized with high precision. Furthermore, the depth d or the surface height of the ring zones can be distributed in the Fresnel member.

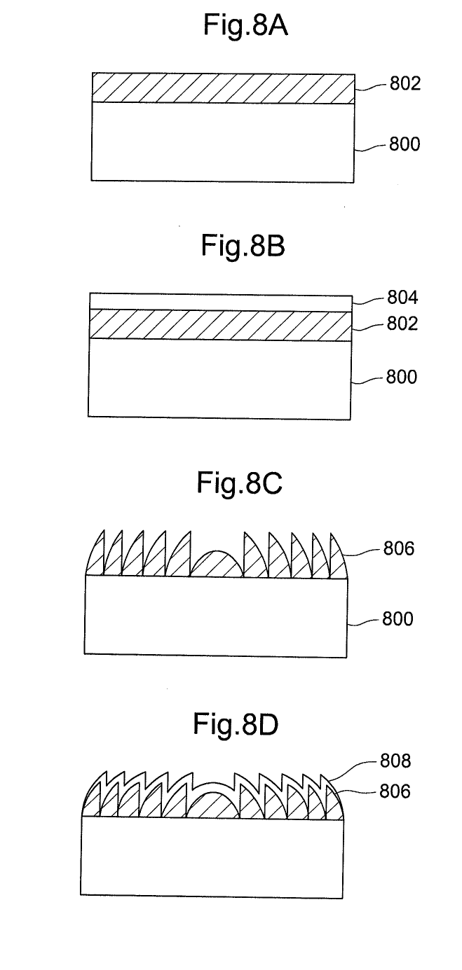

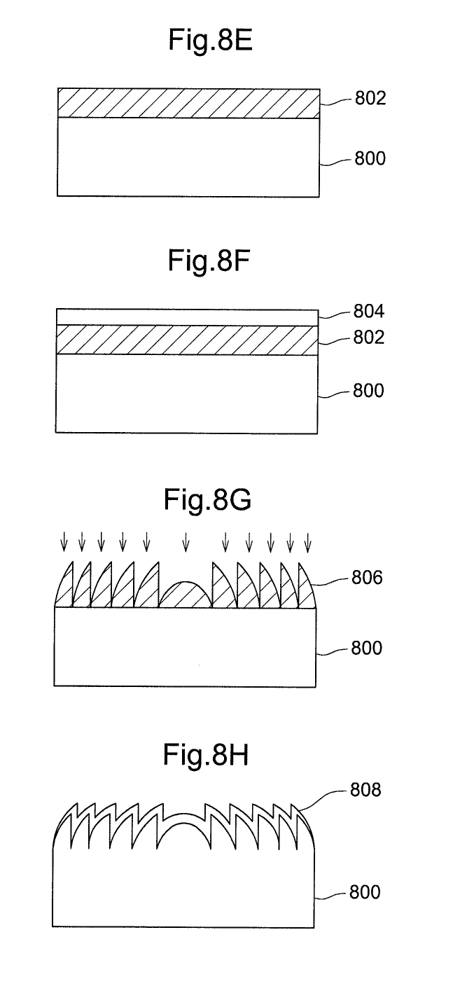

Referring to FIGS. 8A-8D, an exemplary method for forming the Fresnel member by photoresist shaping will be discussed. As shown in FIG. 8A, a photoresist 802 is spin coated on a surface of a substrate 800 and baked. The substrate 800 can be, for example, a glass wafer. The photoresist 802 can be, for example, a regular photoresist for lithography, or a photosensitive polyimide.

As shown in FIG. 8B, a grayscale mask 804 for patterning the photoresist 802 is placed in contact with or in close proximity to the photoresist 802. The mask 804 is developed by irradiation of focused laser beam of any wavelength. Exposure and development of photoresist 802 follows next to form patterned photoresist 806 having a predetermined irregular pattern which includes the ring zones and a predetermined surface height distribution as shown in FIG. 8C. This irregular pattern becomes a reflecting surface shape of the Fresnel member.

As shown in FIG. 8D, a reflecting film 808 is formed on the surface. The surface shape of reflecting film 808 is substantially similar to the shape of the patterned photoresist 802. The reflecting film 806 can be a metallic film or a dielectric multilayer. Finally, the substrate is bonded to another substrate with an adhesive which can be, for example, an ultraviolet curable adhesive, a heat curable adhesive, or an anaerobic adhesive, for example. Preferably, the adhesive is transparent for laser beams with the wavelengths λ1 and λ2 and has substantially the same refractive index as a material used to form the block.

Referring to FIGS. 8E-8H, another exemplary method for forming the Fresnel member by etching will be discussed. As shown in FIG. 8E, a photoresist 802 is coated on a surface of a substrate 800 and baked. The substrate 800 can be, for example, a glass wafer. The photoresist 802 can be, for example, a regular photosensitive photoresist for lithography, or a photosensitive polyimide.

As shown in FIG. 8F, a grayscale mask 804 for patterning the photoresist 802 is placed in contact with or in close proximity to the photoresist 802 for forming patterned photoresist 806 similarly to FIG. 8C. After forming the patterned photoresist 806, an irregular pattern having a predetermined shape is formed on a surface of the substrate 800 by etching.

Referring to FIG. 8G, the patterned photoresist 806 is completely etched so that no photoresist remains. However, etching the patterned photoresist 806 gives the surface of the substrate the irregular pattern as shown in FIG. 8H. That is, the irregular pattern, which has a predetermined shape, and the surface heights of the ring zones are formed on the surface of the substrate 800. Then, reflecting film 808 is formed on the patterned surface of the substrate 808 as shown in FIG. 8H. The substrate can be bonded to another substrate by adhesive. Since a laser beam does not pass through the adhesive, it does not need to be transparent for a laser beam or to have substantially the same refractive index as a material used to form the block.

However, alternatively, the adhesive can be transparent for laser beams with the wavelengths λ1 and λ2 and have substantially the same refractive index as a material used to form the block.

Furthermore, returning to FIG. 2, the integrated prism 210 can be manufactured by first forming the beam splitter 212 and the reflecting coating 216 on a surface of a plate-shaped block on a side of the slope. Then, the block is bonded the substrate 800 with an adhesive, which can be, for example, an ultraviolet curable adhesive, a heat curable adhesive, or an anaerobic adhesive. The large block can be cut in a predetermined shape and polished to thereby manufacture the integrated prism 210. Anti-reflection films may be formed on the side surfaces through which a laser beam is incident or emitted among surfaces of the integrated prism 210.

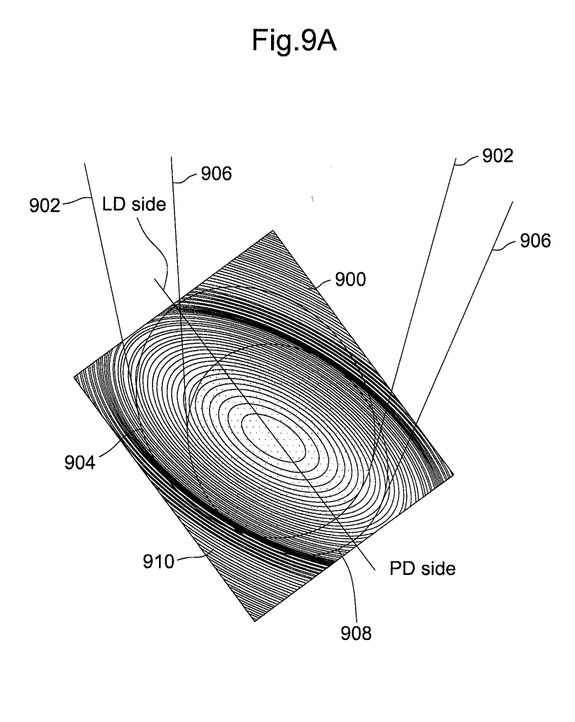

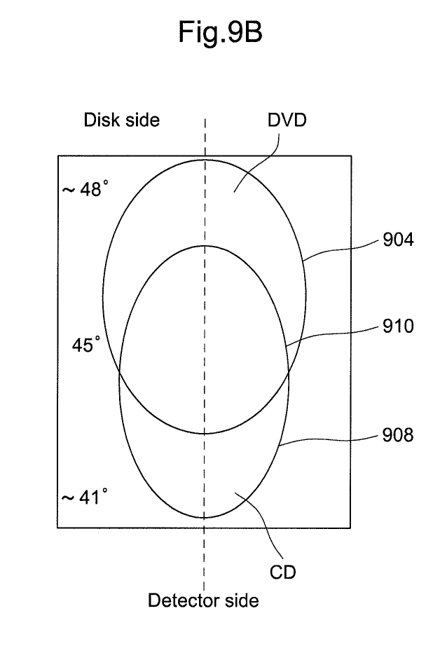

Referring to FIGS. 9A-9B, the distribution of the beam incident angles on a Fresnel member 900 will be discussed. The DVD beam 902 falls on the Fresnel member 900 at a deeper angle (up to approximately 48 degrees) at a spot or envelope 904 disposed closer to the disk (LD side). On the other hand, the CD beam 906 falls on the Fresnel member 900 at a shallower angle (down to approximately 41 degrees) at an envelope 908 disposed closer to the photo-detector (PD side). There is also an intermediate envelope 910 at which both beams partially overlap (intermediate portion).

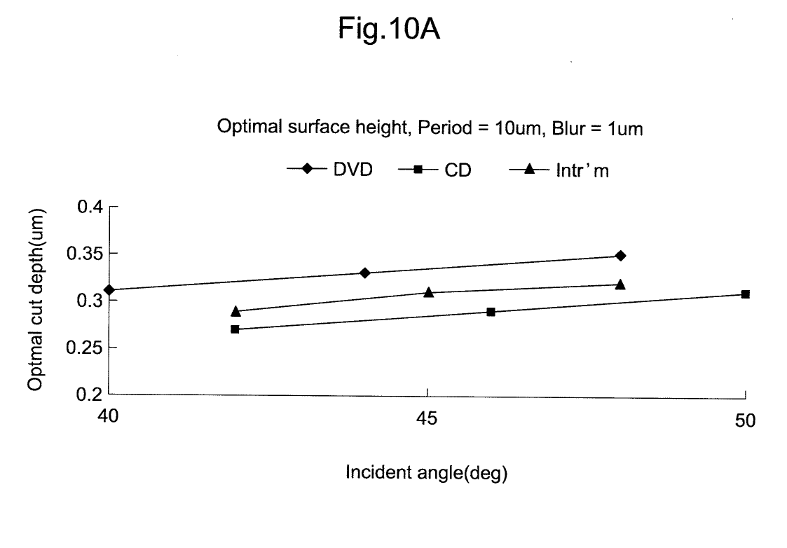

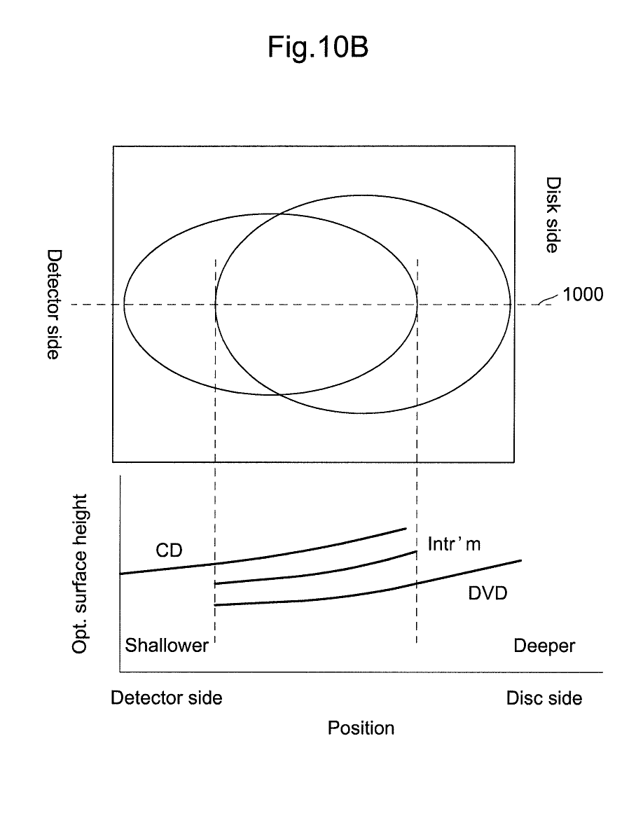

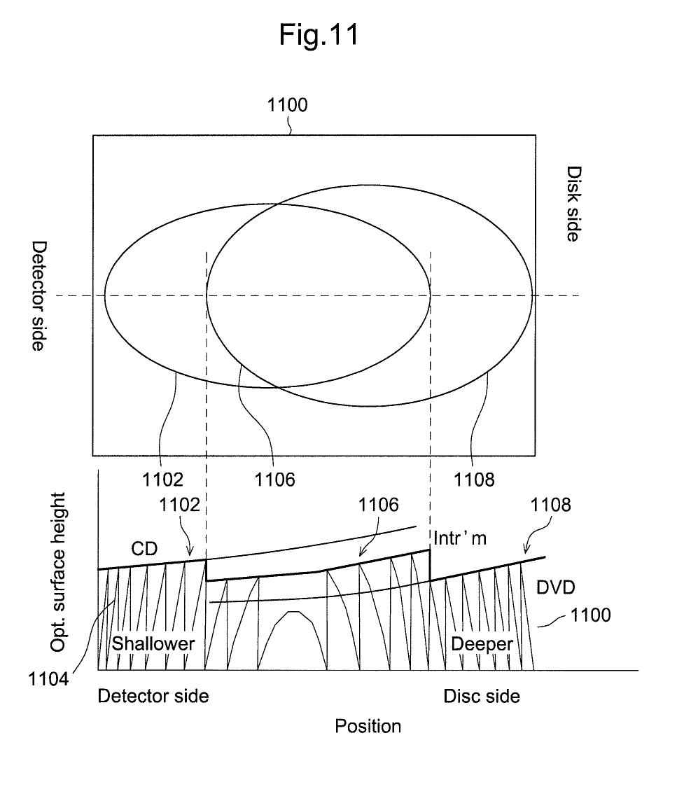

FIGS. 10A-10B show simulation results with regard to the optimal cut depth vs. incident angle for DVD, CD and intermediate wavelength. The cut depth can be used as the surface heights of the ring zones when formed on the surface of the substrate 800 as shown in FIGS. 8A-8H. The incident angle of the beams along the center line 1000 (FIG. 10B) on the Fresnel member surface are, for example, monotonically increasing functions across three envelopes. The optimal cut depth can also be a monotonically increasing function but with different offsets. Various approaches for connecting these discontinuous envelopes will be discussed with regards to FIGS. 11-14.

Referring to FIG. 11, in a Fresnel member 1100 according to an exemplary embodiment, ring zone portions of the ring zones in the three envelopes have predetermined surface heights, which are discontinuously connected, and a predetermined surface height distribution based on the spot shapes for each beam.

Particularly, in a first envelope 1102 on the surface of the Fresnel member 1100 in which solely a laser beam associated with CD wavelength arrives, the optimal surface heights of the ring zones 1104 monotonically increase. In an intermediate envelope 1106 in which the laser beams associated with CD and DVD wavelengths both arrive and overlap, there is a slight offset down from the ring zone portions in first envelope, and then the surface height of each ring zone monotonically increases. In a second envelope 1108 on the Fresnel member surface in which solely a laser beam associated with DVD wavelength arrives, there is a slight offset from the intermediate envelope, and then the surface height of each ring zone monotonically increases. This configuration has the advantage of maximizing the diffraction efficiency for multiple converging beams overlapping each other. However, the discontinuities between the envelopes may introduce stray light.

The Fresnel member 1100 can be made as discussed with respect to FIGS. 8A-8H, wherein the patterned photoresist 806 includes distributions of predetermined surface heights of each of ring zone portions in the first, intermediate and second envelopes which monotonically increase, wherein the distribution of surface heights of the ring zone portions in the first envelope 1102 is offset from the distribution of surface heights of the ring zone portions in the intermediate envelope 1106, wherein the distribution of surface heights of the ring zone portions in the second envelope 1108 is offset from the distribution of surface heights of the ring zone portions in the intermediate envelope.

In this embodiment, the first and second envelopes are beam spot shaped, and the intermediate envelope is a portion at which the first and second envelopes overlap.

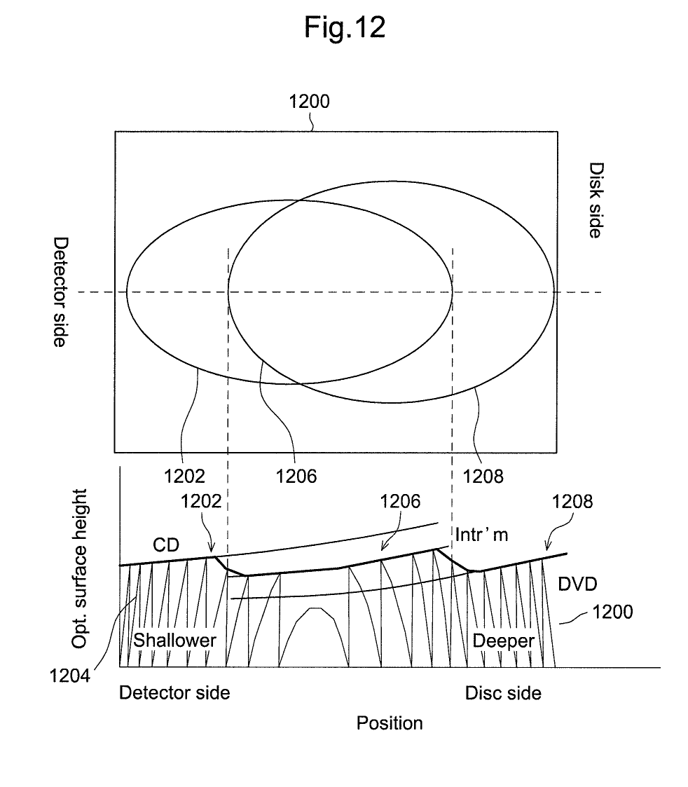

Referring to FIG. 12, in a Fresnel member 1200 according to an exemplary embodiment, the ring zone portions in the envelopes are smoothly connected and the distribution is based on the spot shapes for each beam. Particularly, in a large portion of the first envelope 1202 on the Fresnel member surface in which solely a laser beam associated with CD wavelength arrives, the surface heights of ring zone portions monotonically increase. However, the surface heights of ring zone portions in an end portion of the first envelope 1202 disposed next to the intermediate envelope 1206 are monotonically decreasing to provide a smooth connection with the surface heights of ring zone portions in a beginning portion of the intermediate envelope 1206 disposed next to the first envelope 1202.

A large portion of the surface heights of ring zone portions in the intermediate portion 1206 also monotonically increase, except surface heights of ring zone portions in an end portion of the intermediate envelope disposed next to the second envelope 1208, which are monotonically decreasing to provide a smooth connection with the surface heights of ring zone portions in a beginning portion of the second envelope 1208 disposed next to the intermediate envelope 1206.

The surface heights of ring zone portions in the beginning portion of the second envelope 1208 are also monotonically decreasing to provide the smooth connection with the intermediate envelope 1208. The surface heights of ring zone portions in a remaining portion of the ring zones in the second envelope 1208 monotonically increase. This configuration has the advantage of maximizing the diffraction efficiency for multiple converging beams overlapping each other and reducing the discontinuities between the envelopes.

In this embodiment, the first second envelopes are beam spot shaped, wherein the intermediate envelope is a portion at which the first and second envelopes overlap.

The Fresnel member 1200 can be made by as discussed with respect to FIGS. 8A-8H, wherein the patterned photoresist 806 is formed so that: (1) predetermined surface heights of each of ring zone portions in a large portion of the first envelope monotonically increase and ring zone portions in an end portion of the first envelope disposed next to the intermediate envelope monotonically decrease to provide a smooth connection with the predetermined surface heights of ring zone portions in a beginning portion of the intermediate envelope; (2) predetermined surface heights of each of ring zone portions in a large portion of the intermediate envelope 1206 monotonically increase and ring zone portions in an end portion of the intermediate envelope 1206 disposed next to the second envelope monotonically decrease to provide a smooth connection with the predetermined surface heights of ring zone portions in a beginning portion of the second envelope 1208; and (3) predetermined surface heights of each of ring zone portions in the second envelope monotonically increase.

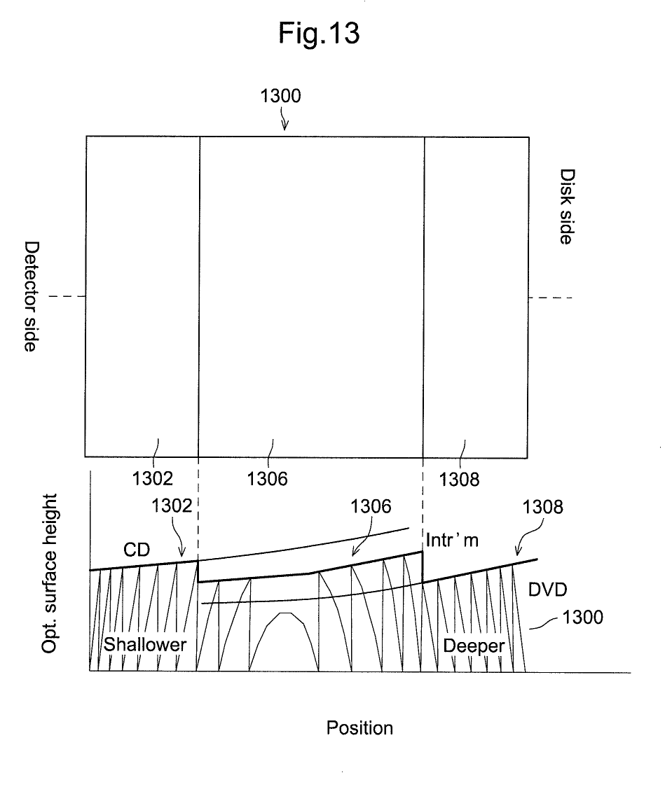

In FIG. 13, the surface heights of the ring zone portions in the three envelopes are discontinuously connected similarly to FIG. 11. However, the distribution is based on rectangular rather than beam spot shaped first, intermediate and second envelopes. This configuration provides a Fresnel member which is easier to design. However, the discontinuity between the envelopes may introduce stray light.

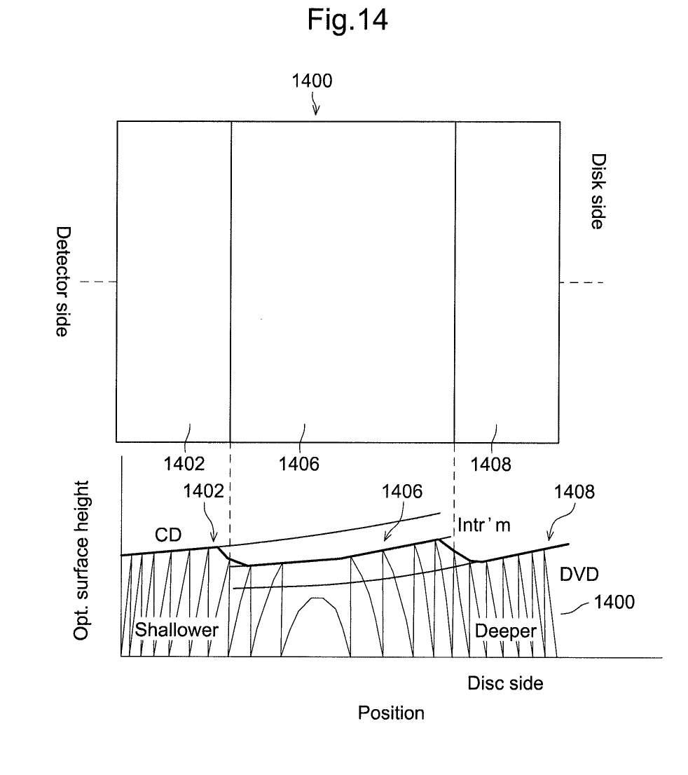

In FIG. 14, the surface heights of the ring zone portions in the three envelopes are smoothly connected similarly to FIG. 12. However, the distribution is based on a rectangular rather than beam spot shaped first, intermediate and second envelopes. This provides a Fresnel member which is easier to design and with reduced discontinuities between the envelopes.

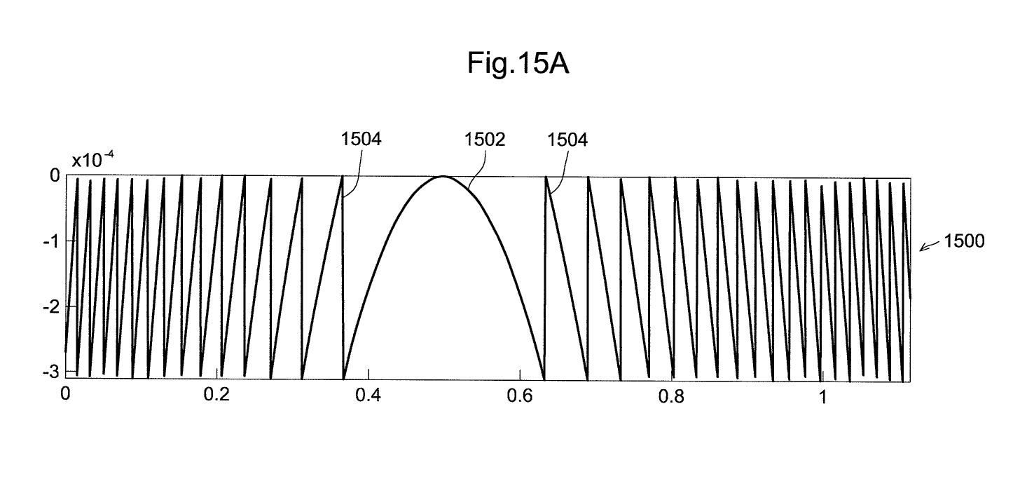

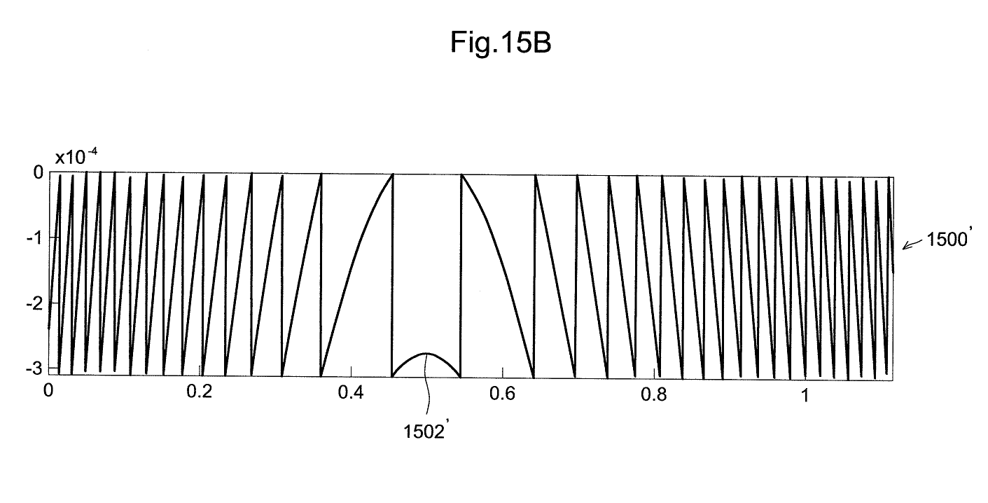

Referring to FIGS. 15A-15B, exemplary Fresnel members formed according to the methods discussed with respect to FIGS. 6A-6B and 8A-8H will be discussed. In FIG. 15A, the Fresnel member 1500 is formed according to a design by which the center portion 1502 is non-diffractive as discussed with respect to FIG. 6A. The center portion extends from the base position to the cut depth.

In FIG. 15B, the Fresnel member 1500′ is formed as discussed with respect to FIG. 6B to minimize the fluctuation of the break period of the Fresnel member. Here, the base line position is different, so that the resultant Fresnel member has a center portion 1502′ that is offset from the cutting depth. That is, the center portion 1502′ does not extend from the base line position to the cut depth and is smaller than the surrounding ring zone portions 1504′. The peak surface height of the center portion 1502 is less than the surface heights of the surrounding ring zones. The resultant Fresnel member is more robust against beam positioning fluctuation due to assembly error, variation of disk layer separation which is typically 55 micrometers between the first and second layers of a DVD double layer disk. The surface heights of the surrounding ring zones may have surface height distributions as discussed above with regards to FIGS. 1114.

The Fresnel member 1500′ can be formed by the method discussed above with regards to FIGS. 8A-8H. The mask 804 can be designed as discussed above with regards to FIGS. 6A-6C or 11-14 so that a curve-shaped central portion and a plurality of ring zones surrounding the curve-shaped central portion are formed on the substrate. Each of the plurality of ring zones having ring zone portions in the first, intermediate and second envelopes, each of the ring zone portions having predetermined surface heights, wherein distributions of the predetermined surface heights of each of ring zone portions in the first, intermediate and second envelopes monotonically increase.

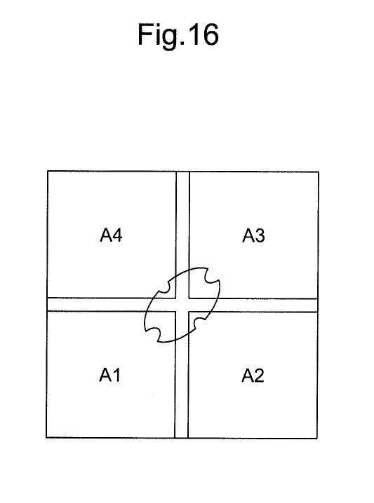

The performance of the Fresnel members of FIGS. 15A and 15B were evaluated by ZEMAX simulation. In order to evaluate the robustness of the Fresnel member, the differential signal on the photo-detector versus the objective lens shift was calculated. The photo-detector is a quad-detector for partitioning the image as shown in FIG. 16 into four segments (A1, A2, A3, A4). The differential signal was calculated according to formula (2): Differential Signal=(A1+A4)−(A2+A3).

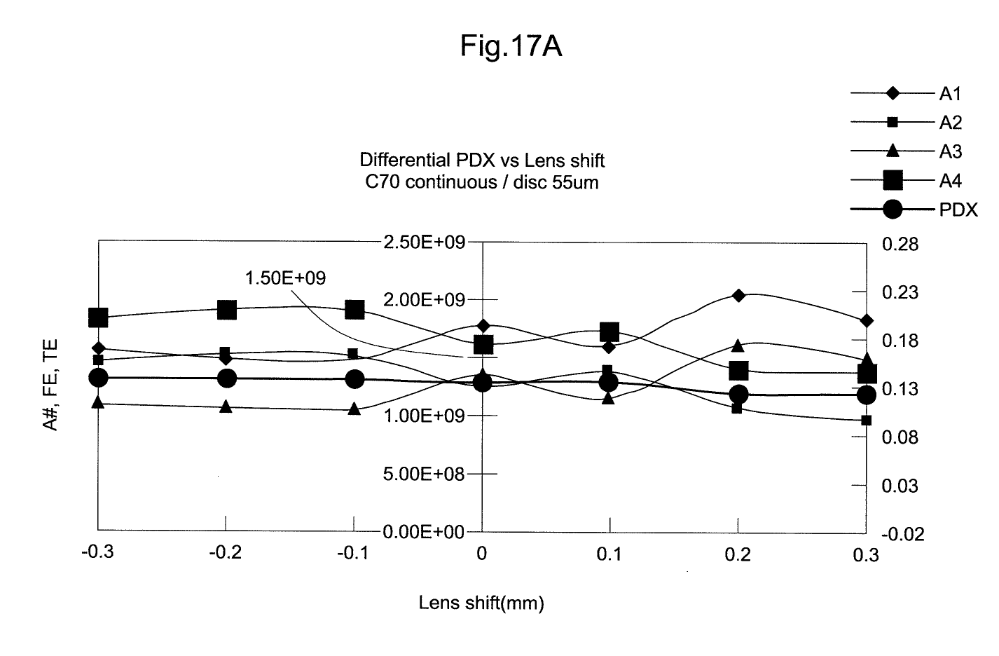

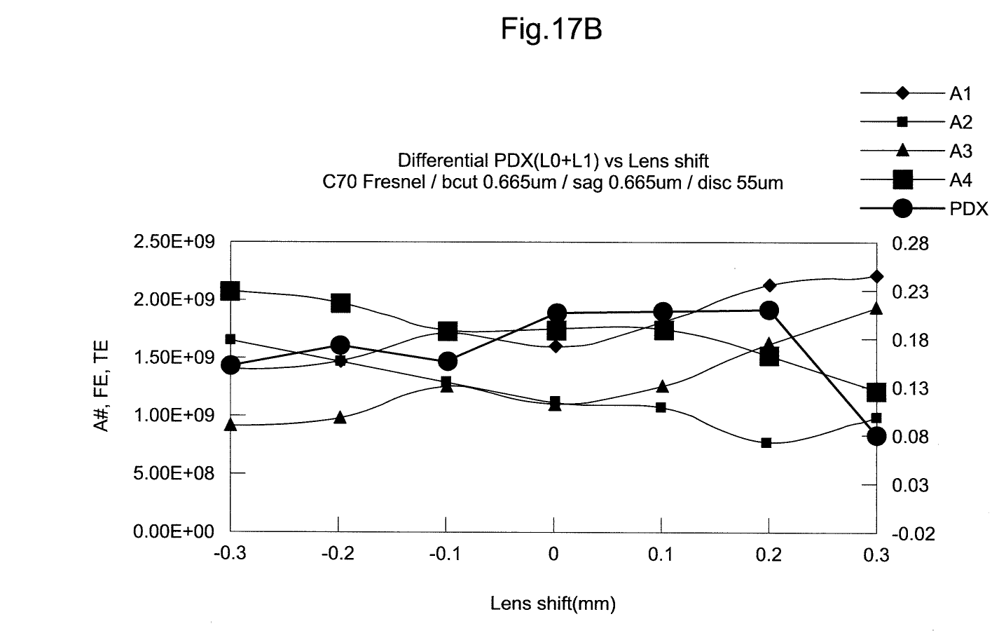

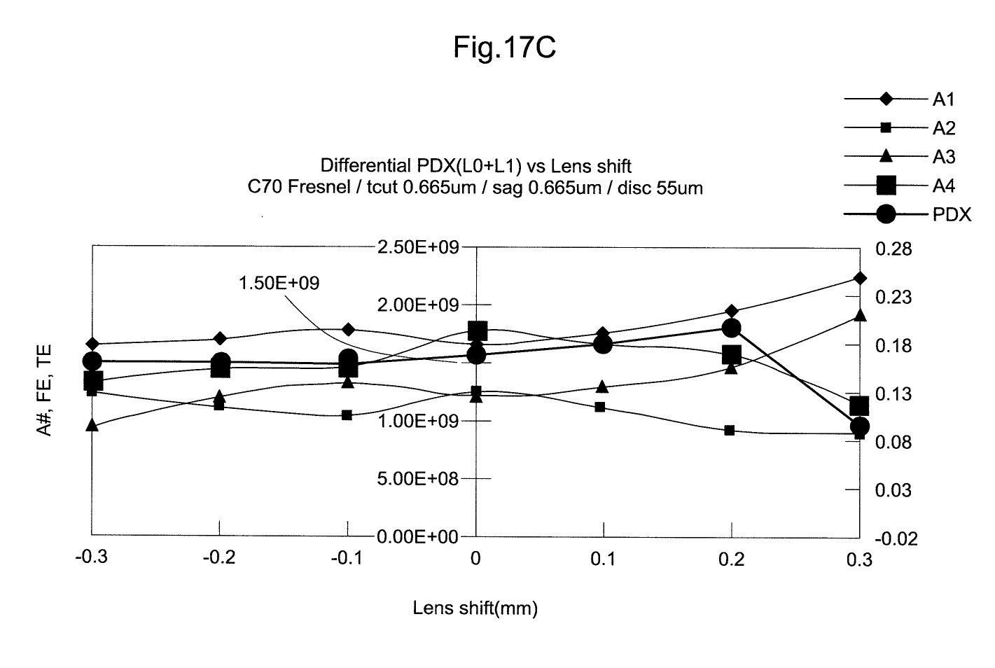

FIG. 17A shows the differential signal of the photo-detector (PDX), and the four partitioned signals (A1-A4) when the optical system includes a regular continuous mirror. The differential signal has stable characteristics against lens shift.

FIG. 17B shows the differential signal (PDX), and the four partitioned signals (A1-A4) when the optical system includes the Fresnel member 1500 of FIG. 15A.

FIG. 17C shows the differential signal (PDX), and the four partitioned signals (A1-A4) when the optical system includes the Fresnel member 1500′ of FIG. 15B. This optical system has better stability in comparison to that shown in FIG. 17B. Further, it has the advantages of compensating for the wavelength dispersion of the diffractive lens and the error associated with the beam convergence angle at which the laser beam hits the Fresnel member as well as compensating for the effect of fabrication error of the Fresnel member and achieving stabilization of the fluctuation of the signal quality while the objective lens scans the disk surface to write/retrieve the data.

It should be noted that the optical system is not limited to a Fresnel member formed only from a mirror or a lens. Further, the optical system is not limited to laser beams associated only with DVD or CD. For example, a laser beam associated with a Blu-ray disk may also be used.

Therefore, the present disclosure concerns an optical system including a laser diode for emitting first and second laser beams having first and second wavelengths, respectively, an integrated prism receiving the first and second laser beams from the laser diode as forward light, and a photo-detector for generating an electrical signal for focus and tracking control based upon at least reflected light received from a Fresnel member in the integrated prism. The Fresnel member receives reflected light associated with the first and second laser beams from a vicinity of an optical disk as return light and includes a curve shaped central portion and a plurality of ring zones surrounding the central portion. The plurality of ring zones include ring zone portions disposed in a first envelope at which return light associated with one of the first and second laser beams is incident and ring zone portions in a second envelope at which return light associated with the other of the first and second laser beams is incident, and ring zone portions disposed in an intermediate envelope at which reflected light associated with both of the first and second laser beams is incident. Preferably, predetermined surface heights of each of the ring zone portions are greater than a peak surface height of the central portion as shown in, for example, FIG. 15B. A distribution of the predetermined surface heights of each of the ring zone portions can be monotonically increasing with discontinuities at points between the first and intermediate envelops and between the intermediate and second envelopes as shown in, for example, FIGS. 11 and 13.

Also, a distribution of the predetermined surface heights of each of the ring zone portions in a larger portion of the first envelope monotonically increase and ring zone portions in an end portion of the first envelope disposed next to the intermediate envelope monotonically decrease to provide a smooth connection with the predetermined surface heights of ring zone portions in a beginning portion of the intermediate envelope as shown in, for example, FIGS. 12 and 14. A distribution of the predetermined surface heights of each of ring zone portions in a large portion of the intermediate envelope monotonically increase and ring zone portions in an end portion of the intermediate envelope disposed next to the second envelope monotonically decrease to provide a smooth connection with the predetermined surface heights of ring zone portions in a beginning portion of the second envelope. A distribution of the predetermined surface heights of each of ring zone portions in the second envelope monotonically increase.

Other embodiments of the optical system will be apparent to those skilled in the art from consideration of the specification and practice of the optical system as disclosed herein. For example, the ring zone portions can be disposed in envelopes shaped differently from the beam-shaped or rectangular shaped envelopes discussed above. It is intended that the specification and examples be considered as exemplary only, with a true scope and spirit of the invention being indicated by the following claims.

1. A method for forming a Fresnel member for an optical system, the Fresnel member configured to receive at least reflected light having a first wavelength in a first envelope, reflected light having a second wavelength different from the first wavelength in a second envelope, and both the reflected light having the first wavelength and the reflected light having the second wavelength in an intermediate envelope, the method comprising:
forming a curve-shaped central portion on a substrate; and
forming a plurality of ring zones surrounding the curve-shaped central portion on the substrate, each of the plurality of ring zones having ring zone portions in the first, intermediate and second envelopes, each of the ring zone portions having predetermined surface heights, wherein distributions of the predetermined surface heights of each of ring zone portions in the first, intermediate and second envelopes monotonically increase.

2. The method of claim 1, wherein the distribution of the surface heights of the ring zone portions in the first envelope is offset from the distribution of surface heights of the ring zone portions in the intermediate envelope, wherein the distribution of the surface heights of the ring zone portions in the second envelope is offset from the distribution of the surface heights of the ring zone portions in the intermediate envelope.

3. The method of claim 2, wherein the first and second envelopes are beam spot shaped, wherein the intermediate envelope is a portion at which the first and second envelopes overlap.

4. The method of claim 2, wherein the first, intermediate and second envelopes are rectangular shaped.

5. The method of claim 1, wherein the forming of the curve-shaped central portion and the plurality of ring zones on the substrate includes:
depositing a photoresist on the substrate and patterning the photoresist according to the curve-shaped central portion and plurality of ring zones; and
depositing a reflecting film on the patterned photoresist to form the curve-shaped central portion and the plurality of ring zones.

6. The method of claim 1, wherein the forming of the curve-shaped central portion and the plurality of ring zones on the substrate includes:
depositing a photoresist on the substrate and patterning the photoresist in accordance with the curve-shaped central portion and plurality of ring zones;
etching the patterned photoresist and the substrate to thereby form the curve-shaped central portion and plurality of ring zones in the surface of the substrate.

7. A method of forming a Fresnel member for an optical system, the Fresnel member configured to receive at least reflected light having a first wavelength in a first envelope, reflected light having a second wavelength different from the first wavelength in a second envelope, and both the reflected light having the first wavelength and the reflected light having the second wavelength in an intermediate envelope, the method comprising:
forming a curve-shaped central portion on a substrate; and
forming a plurality of ring zones surrounding the curve-shaped central portion on the substrate, each of the plurality of ring zones having ring zone portions having predetermined surface heights in the first, intermediate and second envelopes, wherein:
the predetermined surface heights of each of ring zone portions in a large portion of the first envelope monotonically increase and the predetermined surface heights of ring zone portions in an end portion of the first envelope disposed next to the intermediate envelope monotonically decrease to provide a smooth connection with the predetermined surface heights of ring zone portions in a beginning portion of the intermediate envelope;
the predetermined surface heights of each of ring zone portions in a large portion of the intermediate envelope monotonically increase and the predetermined surface heights of ring zone portions in an end portion of the intermediate envelope disposed next to the second envelope monotonically decrease to provide a smooth connection with the predetermined surface heights of ring zone portions in a beginning portion of the second envelope; and
the predetermined surface heights of each of ring zone portions in the second envelope monotonically increase.

8. The method of claim 7, wherein the first and second envelopes are beam spot shaped.

9. The method of claim 7, wherein the first, intermediate and second envelopes are rectangular shaped.

10. The method of claim 7, wherein the forming of the curve-shaped central portion and the plurality of ring zones on the substrate includes:
depositing a photoresist on the substrate and patterning the photoresist according to the curve-shaped central portion and plurality of ring zones; and
depositing a reflecting film on the patterned photoresist to form the curve-shaped central portion and the plurality of ring zones.

11. The method of claim 7, wherein the forming of the curve-shaped central portion and the plurality of ring zones on the substrate includes:
depositing a photoresist on the substrate and patterning the photoresist in accordance with the curve-shaped central portion and plurality of ring zones;
etching the photoresist and the substrate to thereby form the curve-shaped central portion and plurality of ring zones in the surface of the substrate.

12. A Fresnel member for an optical system, the Fresnel member configured to receive at least reflected light having a first wavelength in a first envelope and reflected light having a second wavelength different from the first wavelength in a second envelope, and both the reflected light having the first wavelength and the reflected light having the second wavelength in an intermediate envelope, the Fresnel member comprising:
a plurality of ring zones, each of the plurality of ring zones having ring zone portions having predetermined surface heights in the first, intermediate and second envelopes; and
a substantially curved central portion surrounded by the plurality of ring zones, the central portion having a peak surface height that is less than the predetermined surface heights of each of the plurality of ring zones.

13. The Fresnel member of claim 12, wherein distributions of predetermined surface heights of each of ring zone portions of the ring zones in the first, intermediate and second envelopes monotonically increase, the distribution of surface heights of the ring zone portions in the first envelope is offset from the distribution of surface heights of the ring zone portions in the intermediate envelope, the distribution of surface heights of the ring zone portions in the second envelope is offset from the distribution of surface heights of the ring zone portions in the intermediate envelope.

14. The Fresnel member of claim 12, wherein the first and second envelopes are beam spot shaped, and the intermediate envelope is a portion at which the first and second envelopes overlap.

15. The Fresnel member of claim 12, wherein the first, intermediate and second envelopes are rectangular shaped.

16. The Fresnel member of claim 12, wherein:
predetermined surface heights of each of ring zone portions of the ring zones in a large portion of the first envelope monotonically increase and ring zone portions in an end portion of the first envelope disposed next to the intermediate envelope monotonically decrease to provide a smooth connection with the predetermined surface heights of ring zone portions in a beginning portion of the intermediate envelope;
predetermined surface heights of each of ring zone portions of the ring zones in a large portion of the intermediate envelope monotonically increase and ring zone portions in an end portion of the intermediate envelope disposed next to the second envelope monotonically decrease to provide a smooth connection with the predetermined surface heights of ring zone portions in a beginning portion of the second envelope; and
predetermined surface heights of each of ring zone portions of the ring zones in the second envelope monotonically increase.

17. The Fresnel member of claim 16, wherein the first and second envelopes are beam spot shaped, wherein the intermediate envelope is a portion at which the first and second envelopes overlap.

18. The Fresnel member of claim 16, wherein the first, intermediate and second envelopes are rectangular shaped.

19. An optical system comprising:
a laser diode for emitting first and second laser beams having first and second wavelengths, respectively;
an integrated prism for receiving the first and second laser beams from the laser diode as forward light, the integrated prism including a Fresnel member for receiving reflected light associated with the first and second laser beams from a vicinity of an optical disk as return light; and
a photo-detector for generating an electrical signal for focus and tracking control based upon at least reflected light received from the Fresnel member,
wherein the Fresnel member includes a curve shaped central portion and a plurality of ring zones surrounding the central portion,
wherein the plurality of ring zones include ring zone portions disposed in a first envelope at which return light associated with one of the first and second laser beams is incident and ring zone portions in a second envelope at which return light associated with the other of the first and second laser beams is incident, and ring zone portions disposed in an intermediate envelope at which reflected light associated with both of the first and second laser beams is incident,
wherein predetermined surface heights of each of the ring zone portions are greater than a peak surface height of the central portion.

20. The optical system of claim 19, wherein a distribution of the predetermined surface heights of each of the ring zone portions is monotonically increasing with discontinuities at points between the first and intermediate envelops and between the intermediate and second envelopes.

21. The optical system of claim 19, wherein
a distribution of the predetermined surface heights of each of the ring zone portions in a larger portion of the first envelope monotonically increase and ring zone portions in an end portion of the first envelope disposed next to the intermediate envelope monotonically decrease to provide a smooth connection with predetermined surface heights of ring zone portions in a beginning portion of the intermediate envelope;
a distribution of the predetermined surface heights of each of ring zone portions in a large portion of the intermediate envelope monotonically increase and ring zone portions in an end portion of the intermediate envelope disposed next to the second envelope monotonically decrease to provide a smooth connection with predetermined surface heights of ring zone portions in a beginning portion of the second envelope; and
a distribution of the predetermined surface heights of each of ring zone portions in the second envelope monotonically increase.
